(19) United States
(12) Patent Application Publication
(10) Pub. No.: US 2010/0186226 A1
(43) Pub. Date: Jul. 29, 2010

(54) FLUIDIC SELF-ASSEMBLY FOR SYSTEM INTEGRATION

(75) Inventors: Babak Amirparviz, Seattle, WA (US); Sean Stauth, Seattle, WA (US)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: UNIVERSITY OF WASHINGTON, THE, Seattle, WA (US)

(21) Appl. No.: 12/305,365

(22) PCT Filed: Jun. 25, 2007
(86) PCT No.: PCT/US2007/072038

§ 371 Date: Apr. 2, 2010

Related U.S. Application Data
(60) Provisional application No. 60/816,217, filed on Jun. 23, 2006.

(51) Int. Cl. H05K 3/30

(52) U.S. Cl. 29/832

(57) ABSTRACT

A method for self-assembly is disclosed that accomplishes the assembly process in one step, obviating or mitigating the need for post-processing of an assembled macro-electronic device. Microcomponents are fabricated having a particular shape, and a template with embedded interconnects is fabricated having recessed binding sites that are sized to receive particular microcomponent types. The binding sites include a low melting point alloy for electrically connecting received microcomponents to the interconnect network. The template is placed in a liquid, and the microcomponents are introduced to the liquid such that the microcomponents flow or slide along the template propelled by gravity and/or fluid-dynamic forces and some of them are received into the binding sites, and retained by capillary forces. The liquid is heated before or after introduction of the microcomponents to melt the alloy. The fluid and/or template are then cooled to harden the alloy, binding the microcomponents.

### CROSS-REFERENCE TO RELATED APPLICATION

This application claims the benefit of U.S. Provisional Application No. 60/816,217, filed Jun. 23, 2006, the disclosure of which is hereby expressly incorporated by reference in its entirety, and priority from the filing date of which is hereby claimed.

### BACKGROUND

Macroelectronics is an emerging area of interest in the semiconductor industry. Unlike the traditional pursuit in microelectronics to build smaller devices and achieve higher degrees of integration over small areas, macroelectronics aims to construct distributed active systems that cover large areas. Often, these systems are constructed on flexible substrates with multiple types of components and allow for distributed sensing and control. A number of applications are already under consideration for macroelectronics including smart artificial skins, large area phased-array radars, solar sails, flexible displays, electronic paper and distributed x-ray imagers. A candidate macrofabrication technology must be able to integrate a large number of various functional components over areas exceeding the size of a typical semiconductor wafer, in a cost-effect and time-efficient fashion.

The substrate of choice for many macroelectronic applications is plastic. However, flexible plastic substrates are thermally and chemically incompatible with conventional semiconductor fabrication processes. In order to incorporate electronic devices, a number of venues have been explored for low-temperature integration of semiconductors on plastics. The integration of the semiconductor is followed by a number of complementary steps to build and interconnect functional devices. These material integration methods have demonstrated functional devices on plastic built from amorphous silicon, low temperature polysilicon, and a number of organic semiconductors. Although in a few applications low performance devices are acceptable, in most applications—such as phased-array radar antennas or radio frequency tags—the integrated devices are required to perform at high frequencies with low power consumption.

Generally, devices built using prior art material integration methods suffer from low charge carrier mobility. Typical amorphous silicon transistors have an electron mobility of about 1 cm²/V-s, low temperature polysilicon transistors on plastic have an electron mobility of about 65 cm²/V-s, and organic semiconductor transistors demonstrate charge carrier mobility of about 1 cm²/V-s or much lower. Poor charge carrier mobility in these devices, in comparison to the electron mobility in single crystal silicon transistors, is larger than 1000 cm²/V-s, which translates to poor frequency response and high power consumption. A creative and promising approach uses silicon ribbons released from a wafer and re-assembled on a polymer substrate. The approach has demonstrated electron mobility as high as 100 cm²/V-s, but that remains short of the performance offered by transistors fabricated in single crystal silicon.

An alternative approach for construction of macroelectronic systems is to perform the integration at the device level, instead of the material level. Significant infrastructure is available to cost-effectively fabricate high performance devices on single crystal semiconductor substrates. Even though recent advances in robotic assembly allow for positioning of up to 26,000 components per hour on plastic substrates, the relatively moderate speed, high cost, and limited positional accuracy of these systems make them unsuitable candidates for cost-effective mass production of macroelectronics.

A powerful technology that can meet all the criteria for an effective macrofabrication technology is self-assembly. In a device-level integration approach based on self-assembly, functional devices are batch microfabricated to yield a collection of freestanding components. These components are then manipulated such that at least some of the components self-assemble onto a template, for example onto a flexible plastic substrate, to yield a functional macroelectronic system. Self-assembly, utilized in the fashion outlined above, is an inherently parallel construction method that provides the potential for cost-effective and fast integration of a large number of functional components onto substrates, including unconventional substrates. For example, self-assembly may be suitable for the integration of microcomponents made by incompatible microfabrication processes (e.g., light emitting diodes made in compound semiconductor substrates versus silicon transistors) onto flexible substrates. Key components of a self-assembly-based macroelectronic fabrication technology include: a) development of fabrication processes that generate freestanding micron-scale functional components, b) implementation of recognition/binding capabilities that guide the components to bind in the correct locations, and c) determination of self-assembly procedures/conditions that construct the final macroelectronic system with a high yield.

Self-assembly of micron-scale components and/or millimeter-scale components (“microcomponents”) have been studied previously both for two-dimensional and three-dimensional integration. In two-dimensional integration via self-assembly, a template with binding sites is prepared and a collection of parts is provided and manipulated to self-assemble onto the proper binding sites. The self-assembly procedure is typically performed in a liquid medium to allow for free motion of the microcomponents, and gravity and fluid dynamic forces are used to move the microcomponents and drive the system toward a minimum energy state.

A major drawback of prior art self-assembly methods has been the requirement for post-processing, for example the electrical interconnecting of the microcomponents after they have been self-assembled onto the template. In prior art methods, further processing of the substrate in a clean-room has been necessary to provide electrical connections and complete the assembly procedure. The need for extensive post-processing limits the applicability of prior art self-assembly methods when access to large areas and cost-effectiveness are determining factors. Self-assembly has also been used for three-dimensional integration of freestanding millimeter-scale parts or folding of components placed on ribbons into electrical circuits. In order for the full potential of these techniques to be realized, batch microfabrication processes are needed to generate a large number of micron-scale functional components that can participate in self-assembly.

### SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

A method for self-assembly is disclosed wherein a typically large number of freestanding microcomponents are fabricated. When different types of microcomponents are to be assembled, each type has a distinct shape. The microcomponents may be as large as centimeter scale components, or as small as nanometer scale components, and may be electronic, optoelectronic, micromechanical or the like. The microcomponents include metal pads for attachment to a template.

The template is fabricated with a plurality of recessed binding sites that are sized and shaped to receive the microcomponents. An interconnect network is provided that connects the binding sites, and is preferably embedded or otherwise integral to the template. Each of the binding sites is further provided with a low melting temperature alloy for electrically connecting the received microcomponent to the interconnect network.

The template is immersed in a heated liquid that is hotter than the alloy melting temperature, but not hot enough to damage the template or the microcomponents. The microcomponents are added to the heated liquid such that at least some of the microcomponents are received into the recessed binding sites such that the metal pads engage the molten alloy. The template is then allowed to cool, for example by allowing the liquid to cool, removing the template and allowing the template to cool, or through active cooling. The low melting point alloy solidifies, completing the connection of the microcomponents to the interconnect network.

In a particular embodiment of the present method, field effect transistors comprise at least some of the microcomponents, and the transistors may be fabricated with silicon nitride used both as a diffusion mask and as a gate dielectric layer. The microcomponents may be formed using a silicon-on-insulator wafer.

In a particular embodiment of the present method the distinct shapes of the microcomponents include one or more shapes from the group comprising circular, square, rectangular, triangular, and cruciform, and the metal pads are formed on only one side of the microcomponents.

In a particular embodiment of the present method the template is formed on a plastic substrate such as polyester or polyethylene terephthalate, with binding sites formed with an epoxy-based clear negative photoresist.

In a particular embodiment an alloy having melting temperature of less than about 80° C. is applied to the binding sites using a dip-coating technique.

In a particular embodiment the template is immersed at an angle between about 20-60 degrees in a heated ethylene glycol or glycerin based liquid that is agitated to facilitate movement of the microcomponents.

These and other aspects of the present invention will become apparent upon reviewing the disclosure contained herein.

### DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1 is a block diagram outlining an embodiment of the method according to the present invention;

FIG. 2 illustrates a heterogeneous self-assembly process outlined in FIG. 1, wherein microcomponents are introduced over a template submerged in a liquid medium and self-assembly occurs as the microcomponents fall into complementary shaped wells, and become bound by the capillary forces resultant from a molten alloy;

FIGS. 3A and 3B illustrate details of the self-assembly process of FIG. 2, showing a single microcomponent and a portion of the substrate or template that receives the microcomponent. In FIG. 3A a microcomponent having a generally rectangular shape approaches a binding site with complementary shape; in FIG. 3B the microcomponent is held by capillary force resultant from a molten alloy in the binding site;

FIGS. 4A-4F illustrate a currently preferred process for fabrication of freestanding microcomponents such as those shown in FIG. 2.

### DETAILED DESCRIPTION

A fluidic self-assembly method for batch fabrication of small, typically micron-scale, functional devices is disclosed. An exemplary application for the method is the batch assembly of a large number of silicon field effect transistors (“FETs”) and diffusion resistors onto a flexible plastic substrate or template. A fabrication method is disclosed wherein the actual assembly of the functional devices onto the template is accomplished in a single step, eliminating or greatly reducing the need for self-assembly post-processing. The method allows for the integration of a very large number of microcomponents onto a large-area template. The method may be applied to assembling devices having a characteristic dimension on the order of nanometers to components having a characteristic dimension on the order of a centimeter. Moreover, the devices may be electronic, optical or optoelectronic, micromechanical or the like.

Therefore, as used herein the term “microcomponent” is expressly defined to mean any device (electronic, optoelectronic, micromechanical or the like) having a characteristic length that may be as small as nanometers to as large as centimeters. It is contemplated that the method will find most application in applications utilizing devices having a characteristic dimension on the order of one millimeter or much smaller.

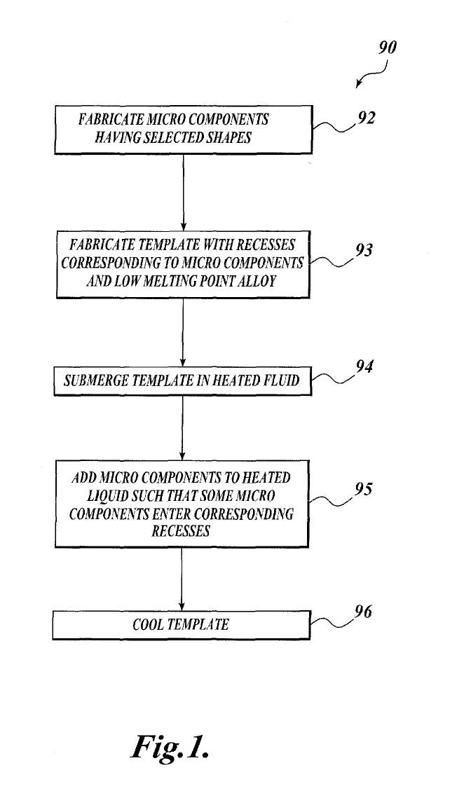

An embodiment of the present method 90 is summarized in the block diagram shown in FIG. 1. In this method, functional devices or microcomponents are fabricated 92 wherein each type of microcomponent has a particular shape. As a simple example, FETs may be fabricated to have a cruciform shape, and diffusion resistors may be fabricated to have a triangular shape.

A substrate or template is fabricated 93 having binding cites defining recesses that correspond to the shapes of the fabricated microcomponents so that a particular microcomponent type is keyed to be accepted into a corresponding recess in the template. An interconnecting network is embedded into the template, connecting the recesses in a desired manner, and a low temperature alloy is provided in the recesses for electrically connecting the received microcomponents to the interconnect network.

The template is then placed into a liquid that is heated sufficiently to liquefy or melt the alloy 94, but is not hot enough to damage the template or the microcomponents. The fabricated microcomponents are introduced into the heated liquid 95, such that at least some of the microcomponents settle into corresponding recesses. At least a portion of the microcomponents generally slide over the surface of the template until a microcomponent suitably encounters a corresponding recess. It will be appreciated that this may include multiple steps, including, for example, orienting the template at an angle with respect to gravity, directing the microcomponents and heated liquid to flow over the template, agitating the heated liquid, recycling a portion of the liquid (with suspended microcomponents) to reflow over the template, and the like. Fluid dynamic forces and gravity transport the microcomponents and guide the system toward a minimum energy state. In addition, capillary forces resulting from the molten alloy in the individual recesses assist in retaining and binding the microcomponents to the target location. It is contemplated that this assembly step may be performed in a batch mode wherein the template is submerged into a container of heated liquid and then the microcomponents are added, or the assembly may be conducted in a continuous mode, for example, maintaining a stream of components and heated liquid that receives templates in an assembly-line manner.

The assembled template is then allowed to cool 96, such that the low-melting point alloy solidifies, mechanically and electrically securing the microcomponents to the template. For example, in a batch mode the fluid may be cooled (or allowed to cool) to a sufficiently low temperature. Alternatively, the template may be removed from the heated liquid.

The efficacy of the method described herein has been tested and verified through demonstrations of various aspects of the self-assembly method, including: (i) simultaneous assembly of multiple shapes of microcomponents onto a common substrate; (ii) self-assembly of single-crystal silicon FETs and diffusion resistors to create active high performance electronic circuitry on plastic substrates; and (iii) rapid and high yield self-assembly of approximately 10,000 silicon microcomponents onto a plastic substrate. Through these demonstrations, the self-assembly technique is verified to be extendable to multiple types of microcomponents, to be able to integrate high performance active circuitry on plastic in a single step, and to be massively parallel by nature.

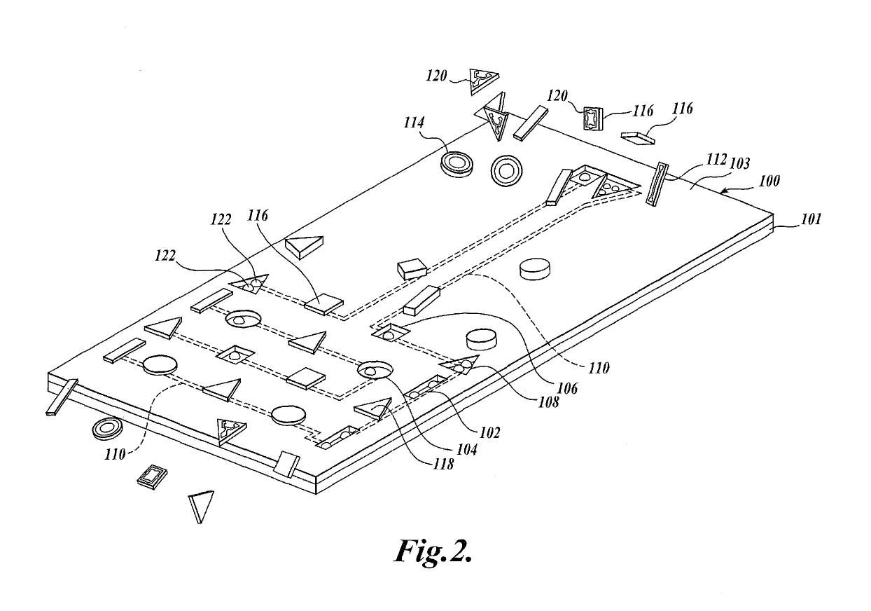

FIG. 2 illustrates the fluidic self-assembly discussed above, wherein a template 100 is disposed in a heated liquid (liquid not shown, for clarity). Although in this exemplary embodiment the template 100 is substantially planar, it will be readily apparent that the method may be used with non-planar templates, for example to assembly microcomponents onto a three-dimensional The template 100 includes a plurality of recesses or binding sites 102, 104, 106, 108 that are specifically shaped to accommodate particular microcomponents 112, 114, 116, 118. A low-melting point alloy 122 is provided in the binding sites for electrically connecting the microcomponents to the embedded interconnect 110. The microcomponents include contacts or metal pads 120, that are preferably disposed only on the side of the microcomponent that faces downwardly into the recess defined by the binding site. In the present example, the metal pads 120 are Au/Cr interconnects.

For example, and not by way of limitation, in FIG. 2 the template 100 includes rectangular binding sites 102, round binding sites 104, square binding sites 106 and triangular binding sites 108. An embedded interconnect network 110 connects the binding sites in a desired manner, as discussed in more detail below. Correspondingly-shaped microcomponents, e.g., rectangular 112, circular 114, square 116, and triangular 118 microcomponents, which are designed to be received by the correspondingly-shaped binding sites, are also shown, wherein some of the microcomponents have been captured in a like-shaped recess and some are not yet captured.

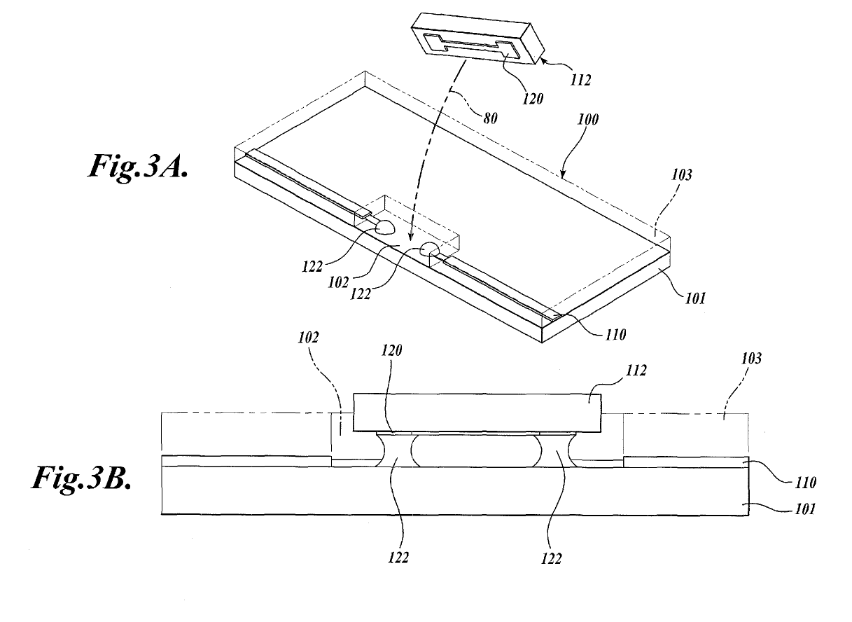

Refer now also to FIGS. 3A and 3B showing a detailed cross-sectional view of a small portion of the template 100. A generally rectangular binding site 102 is illustrated and a corresponding silicon microcomponent 112 (for example, a resister) that is shaped to fit into the recess defined by the binding site 102. FIG. 3A shows the microcomponent 112 entering the binding site 102, as indicated by arrow 80. FIG. 3B shows the microcomponent 112 disposed in the binding site 102, wherein the molten alloy 122 contacts the metal pads 120 to form electrical connections with the interconnects 110.

The embedded interconnects 110 may be produced using any conventional method, as are well known in the art. For example, in the present embodiment, the template 100 is formed with a plastic substrate base layer 101 and an SU-8 upper layer 103 (shown in phantom for clarity) that defines the binding site recesses. The interconnects 110 are disposed therebetween. The interconnects 110 connect the binding sites 102, 104, 106, 108 such that when the binding sites are occupied, a desired circuit is formed. The low melting point alloy 122 provides a mechanism for electrically connecting the microcomponents to the interconnects 110.

As described in more detail below, the template 100 is submerged in a heated liquid that is hot enough to melt the alloy 122, but not hot enough to damage the template 100 or the freestanding microcomponents 112, 114, 116, 118. The microcomponents are introduced into the heated liquid medium such that they slide over the template 100 and a portion of the microcomponents enter and are retained in the corresponding binding sites, aided by fluid flow and gravity. The metal pads 120 on the retained microcomponents engage the molten alloy 122 at the bottom of the binding site. The resultant capillary force keeps the microcomponent in the recess, preventing the fluid flow from dislodging the received microcomponent.

After completion of the self-assembly process, the temperature of the heated liquid medium is lowered such that the molten alloy 122 solidifies to fix the mechanical and electrical connections between the microcomponents 112, 114, 116, 118 and the interconnects 110 on the template 100. It will be appreciated that this method allows for one-step assembly of the final functional device without the need for significant further processing after the self-assembly is complete.

Exemplary Method for Fabricating Microcomponents

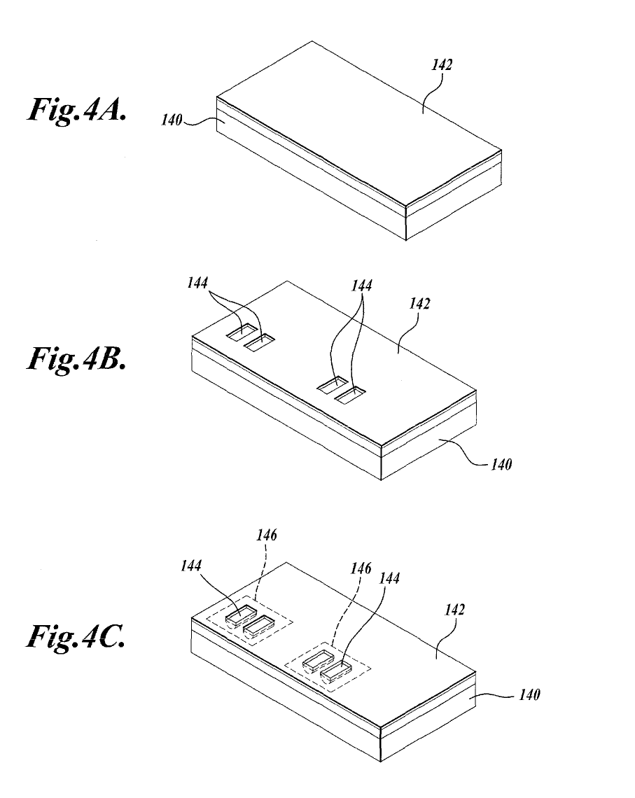

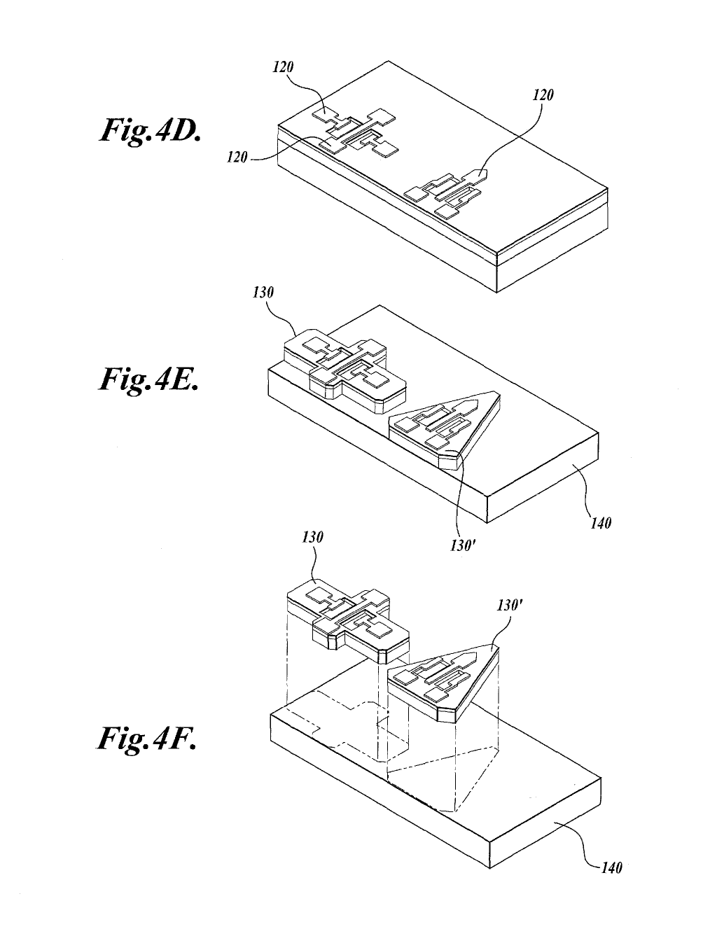

A method of constructing freestanding microcomponents 130, 130′ for example n-type FETs, will now be described, with reference to FIGS. 4A-4F. The n-type FETs may be fabricated on, and released from, a silicon-on-insulator (“SOI”) wafer. Each microcomponent includes metal Cr/Au pads 120, preferably on only one side, and has a specifically defined shape unique to the particular microcomponent type. The microcomponent shapes are designed to be mutually exclusive from one another to preclude or reduce the likelihood of erroneous self-assembly.

To fabricate freestanding n-type FETs that are compatible for use with the present self-assembly process, a relatively straightforward fabrication method may be used that requires only three photolithography masks and one diffusion step. Two different shapes of FETs, triangular FETs 130 and cruciform FETs 130′, were fabricated for testing the assembly process, as well as rectangular phosphorous diffusion resistors. Fabrication of the FETs 130, 130′ is unusual, however, because silicon nitride (Si₃N₄) is used both as a diffusion mask and as the gate dielectric layer. Silicon dioxide is the standard gate dielectric in most FETs, but the hydrofluoric (“HF”) acid used to release the components in the present process would readily etch a silicon dioxide dielectric layer. Therefore, a 200 nm thin low-pressure chemical vapor deposited (“LPCVD”) low-stress Si₃N₄ is used to serve as the gate dielectric layer, as well as serving as the mask during phosphorus diffusion.

We started the device microfabrication process with an SOI wafer 140 with 10 μm to 20 μm thick <100>p-type 1-10 Ω-cm device layers, and 0.5 μm to 1 μm thick buried silicon dioxide layers. Following LPCVD silicon nitride 142 deposition (FIG. 4A) we photo-lithographically patterned the wafers 140 and etched the silicon nitride 142 through photoresist openings with reactive ion etching to open the n-wells 144 (FIG. 4B). We then removed the photoresist and used spin-on phosphorus dopant glass and drive-in at 950° C. for 30 minutes to dope the source and the drain regions 146 (FIG. 4C). Following diffusion, the dopant glass is removed with a 1:10 buffered oxide etch. Next a low-temperature (850° C.) dry oxidation is performed on the wafers, and the remaining silicon dioxide is stripped with a buffered oxide etch.

To define the metal pads 120 a photolithography step is used, followed by evaporation of Cr/Au (10 nm/200 nm) and lift-off (FIG. 4D). A third photolithography step defines the shape of the microcomponents 130, 130′. The photoresist is used as a masking layer to first remove the top silicon nitride layer with reactive ion etching followed by a deep reactive ion etching (“DRIE”) step to etch the device layer down to the buried silicon dioxide in the SOI structure (FIG. 4E). The photoresist is then removed with acetone and the transistors are released by immersing the wafers in 49% HF acid bath for about twenty minutes (FIG. 4F). Exposure to HF acid removes the buried silicon dioxide layer and releases the microcomponents into the solution. We isolated, rinsed, and stored the powder-like collection of freestanding microcomponents 130, 130′ in de-ionized water. It will be readily apparent to persons of skill in the art that other methods may be used to fabricate free-standing microcomponents, and that components other than FETs may be fabricated to any particular shape.

Exemplary Method for Fabricating Template

To prepare the templates for the self-assembly process we used a thermally stable 100 μm thick polyester substrate. We patterned the substrate surface with photolithography followed by low power (approximately 50 W) sputtering of TiW/Au (10 nm/200 nm) and lift-off to generate the metal interconnects. To form the binding sites with the desired geometry and depth (10-20 μm) we used an epoxy-based clear negative photoresist, e.g., SU-8. The binding site wells were designed to accommodate a microcomponent with a complementary shape and express a flat surface after the completion of the process. We used dip-coating in a low melting point alloy e.g., Small Parts Inc., part # LMA-117: Bi(44.7%)-Pb(22.6%)In(19.1%)Sn(8.3%)Cd(5.3%), (melting point 47° C.) pool to position the alloy on gold metal pads at the bottom of the binding sites.

The templates were fabricated using standard clean-room photolithography and metallization techniques; however all processes were adjusted to ensure the substrate temperature did not exceed 80° C. Temperatures higher than 80° C. caused the substrate to warp, thus making mask alignment during photolithography very difficult. Therefore, for example with this particular substrate, the low melting point alloy must have a melting temperature less than about 80° C., and is preferably less than about 70° C.

In addition, directly prior to use for self-assembly, we thoroughly cleaned the parts using a piranha etch (3:1 mixture of concentrated sulfuric acid (H₂SO₄ and hydrogen peroxide (H₂O₂)) to ensure that the Cr/Au interconnect on the elements is clean and can bind to the molten alloy on the plastic substrate.

It will be apparent to a person of skill in the art that other materials may be used for the template, including for example polyethylene terephthalate, sometimes referred to as PET.

Exemplary Method for Self-Assembly

To perform the self-assembly process we heated a container of ethylene glycol to 70° C. We immersed the template immediately after alloy dip-coating in the ethylene glycol solution. Heated ethylene glycol had a lower viscosity that allowed for better motion of microcomponents in the liquid and melted the alloys positioned on bonding pads on the template. Separately, we cleaned the collection of microcomponents with a short piranha etch (H₂SO₄: H₂O₂, 3:1 v/v), rinsed them with de-ionized water and introduced them over the submerged template, which was tilted approximately 20 to 60 degrees to the horizontal. The pH of the solution was lowered to 3 by addition of HCl to break the surface oxide forming on the molten alloy. The microcomponents were allowed, or fluid-dynamically impelled, to flow past the binding sites over the template and bond.

We provided a constant fluid motion with a pipette and positioned the self-assembly medium over a shaker table to provide extra external agitation. Fluidic and gravitational forces moved the microcomponents and broke apart aggregations of microcomponents that occasionally formed. After the completion of the self-assembly process, we lowered the temperature of the ethylene glycol solution to room temperature to solidify the alloy and make the connections permanent and removed the template from the solution for further test and measurement.

We found that long exposure to acid at elevated temperatures adversely affected the adhesion of the SU-8 layer defining the binding site geometry to the plastic substrate. An alternative method to perform the self-assembly process was to avoid the addition of acid to the self-assembly medium and rely primarily on geometric shape matching to complete the template. After the completion of the shape matching step, hydrochloric acid was added to break the alloy surface oxide, and the self-assembly medium temperature was raised for 1-2 minutes to 90° C. to form the capillary bonds between the microcomponents and the template. Subsequent lowering of the temperature yielded permanent and reliable mechanical and electrical connections between the microcomponents and the templates.

It will be readily apparent to persons of skill in the art that other liquids may alternatively be heated and used in the self-assembly process, including for example, glycerol, a water-soluble and hygroscopic sugar alcohol.

In applications wherein multiple different microcomponents are to be self-assembled onto a template, the microcomponents may be introduced into the liquid simultaneously (as indicated in FIG. 2), or the microcomponents may be sequentially introduced into the liquid, wherein one type of microcomponent is self-assembled onto the template before a second type of microcomponent is introduced. It will be appreciated that the sequential introduction of microcomponents may be useful, for example, when it is desirable to allow larger microcomponents to be received into corresponding binding site recesses, before smaller microcomponents are introduced, thereby alleviating the risk of interference between the microcomponents during self-assembly.

Results and Discussion

Shape recognition between elements and binding sites on the plastic substrate allowed for the simultaneous assembly of different types of elements. This indicates that the self-assembly scheme can be made programmable, e.g., multiple types of components can be integrated accurately onto a common platform.

Differences between the assembly rates of different element shapes were noticeable. Rectangles and circles self-assemble much more readily than squares and triangles. Many of the differences can be attributed to component mobility across the substrate. Component-on-component entanglement and incorrect component-substrate binding were more pronounced for squares and triangles. The direction of the fluid flow also aided in the alignment of the rectangular microcomponents with the binding sites.

A logic inverter, for example, was just one of multiple circuit configurations tested for use with self-assembly. The self-assembly of single FETs was tested, as were current mirrors and voltage and current amplifiers. In particular, the electron mobility of the FETs, as measured on plastic, was 592 cm²/V-s, with a source resistance of 218 Ω.

In a test of the self-assembly method was undertaken using circular microcomponents fluidically self-assembled onto a template with 10,000 binding sites.

Over 97% self-assembly yield was achieved across the entire template. The process involved the manual introduction of elements onto the substrate, followed by agitation to pass the elements across the binding sites. After the completion of each pass resulting in either the bonding of the elements to the template or their fall to the bottom of the self-assembly vessel, the elements were collected and re-introduced on the template. This procedure was repeated 5 times for each template to achieve high-yield self-assembly. It is contemplated that this process is readily amenable to automation.

To quantify the likelihood of proper biding in the self-assembly process, we performed additional assembly experiments with substrates containing only 600 binding sites and circular elements. Starting with completely empty binding sites (0% self-assembled), we introduced a large number of elements (about an order of magnitude more than the number of binding sites) over the substrate and measured the self-assembly yield after all the excess elements had fallen off the template (one element pass completed). We continued this procedure, each time passing roughly the same number of elements over the substrate, until the self-assembly yield was approximately 100%. After each pass we recorded the assembly yield defined as the number of correctly assembled elements divided by the total number of binding sites on the template. We repeated this experiment six times. More than 80% of the binding sites were occupied by self-assembly during the first pass; after five passes the self-assembly yield nears 100% for a template with 600 binding sites. The time taken for each element pass was five minutes. Thus almost near perfect self-assembly was achieved in 25 minutes.

Self-assembly provides a powerful tool for production of macroelectronic systems. We have demonstrated that microfabrication processes can be developed to make functional microcomponents, such as single crystal field effect transistors, in a powder-like collection, and that this collection of microcomponents can be self-assembled onto a flexible plastic template in a single step to yield functional circuitry. The method allows for integration of microcomponents that are made independently in potentially incompatible microfabrication processes. We have demonstrated functional devices and circuits on plastic substrates with measured electron mobility exceeding 590 cm²/V-s constituting almost an order of magnitude improvement over the prior state-of-the-art in charge carrier mobility of semiconductor devices operating on plastic. More importantly we show that self-assembly, as delineated here, can provide very high yields exceeding 97%.

Although the self-assembly experiments were performed in a laboratory with non-production equipment and manual introduction of parts, the self-assembly rate of 10,000 units per 25 minutes for 100 μm microcomponents rivals the assembly rate of the fastest multimillion dollar robotic assemblers. These results demonstrate the high potential of self-assembly as a method for producing macroelectronics. It is believed that the self-assembly rate can be improved by orders of magnitude via automation of the self-assembly set-up.

We relied on a simple shape matching effect to control the binding locations of multiple microcomponent types on the template and used capillary forces to make connections between the microcomponents and the templates. Both of these effects (shape matching and self-assembly driven by capillary forces) are scaleable down to much smaller sizes. In particular, the present method may be used in macroelectronic applications requiring much more complex microcomponents, for example using components carrying tens of interconnected transistors, or more. It will be appreciated by persons of skill in the art that the microfabrication processes described herein can be easily modified to accommodate such applications.

It will be appreciated that although the present method has been described in the context of assembling multiple different types of microcomponents onto a template wherein each type of microcomponent has a unique shape, the method is equally applicable to assembling a large number of microcomponents of a single type onto a template. The shape of the component may be symmetric, or may be keyed to achieve a desired orientation of the microcomponent.

While illustrative embodiments have been illustrated and described, it will be appreciated that various changes can be made therein without departing from the spirit and scope of the invention.

1. A method for assembling a plurality of microcomponents onto a template, the method comprising the steps of:
fabricating a plurality of microcomponents of more than one type, wherein each type of microcomponent has a distinct shape, and further wherein each of the microcomponents have metal pads;
fabricating a template having a plurality of recessed binding sites wherein each binding site is shaped to correspond to one of the types of microcomponents, the template having an interconnect network interconnecting the plurality of binding sites, and wherein each of the binding sites includes an alloy having a low melting temperature;
immersing the template in a heated liquid that is hotter than the alloy melting temperature;
placing at least some of the plurality of microcomponents into the heated liquid such that at least some of the microcomponents are received into the plurality of recessed binding sites with their metal pads engaging the alloy; and
cooling the alloy thereby connecting the received microcomponents to the interconnect network.

2. The method of claim 1, wherein the plurality of microcomponents include transistors.

3. The method of claim 2, wherein the transistors are fabricated with silicon nitride used both as a diffusion mask and as a gate dielectric layer.

4. The method of claim 1, wherein the distinct shapes of the microcomponents include one or more shapes from the group comprising circular, square, rectangular, triangular, and cruciform.

5. The method of claim 1, wherein the metal pads are formed on only one side of the microcomponents.

6. The method of claim 1, wherein the microcomponents are formed on a silicon-on-insulator wafer and released from the wafer using an acid bath to produce freestanding microcomponents.

7. The method of claim 1, wherein the template includes a substrate formed from a material selected from the group polyester and polyethylene terephthalate.

8. The method of claim 7, wherein binding sites are formed on the substrate with an epoxy-based clear negative photoresist.

9. The method of claim 7, wherein the alloy melting temperature is less than about 80° C.

10. The method of claim 7, wherein the alloy is applied to the template using a dip-coating technique.

11. The method of claim 1, wherein the heated liquid comprises a liquid selected from the group ethylene glycol and glycerol.

12. The method of claim 11, wherein the liquid is heated to about 70° C.

13. The method of claim 1, farther comprising the steps of cleaning the microcomponents with a short piranha etch and rinsing the microcomponents with de-ionized water prior to placing the microcomponents in the heated liquid.

14. The method of claim 1, wherein the step of immersing the template in the heated liquid includes orienting the template at an angle of approximately 20 to 60 degrees with respect to horizontal.

15. The method of claim 1, further comprising the step of fluid-dynamically urging the microcomponents to flow past the binding sites.

16. The method of claim 15, further comprising the step of recirculating a portion of the microcomponents after they have flowed past the binding sites.

17. The method of claim 1, further comprising the step of agitating the heated liquid.

18. The method of claim 1, further comprising the step of lowering the heated liquid temperature to solidify the alloy.

19. The method of claim 1, wherein the step of placing at least some of the plurality of microcomponents into the heated liquid is accomplished in several steps wherein a first type of the plurality of microcomponents is first placed into the heated liquid and then a second type of the plurality of microcomponents is subsequently placed into the heated liquid.

20. The method of claim 1, wherein the plurality of microcomponents comprise one or more of electronic microcomponents, optoelectronic microcomponents, and micromechanical microcomponents.

21. A method of assembling a plurality of microcomponents onto a template comprising the steps of:
fabricating a plurality of first microcomponents having a first shape and a metal pad interconnect;
fabricating a template with a plurality of recessed binding sites shaped to receive the first microcomponents, the binding sites being electrically connected with an interconnect network, and further comprising a low melting temperature alloy;
immersing the template in a liquid;
placing the first microcomponents into the liquid such that at least some of the first microcomponents are received into at least some of the recessed binding sites such that the received microcomponent metal pad interconnects engage the low melting temperature alloy;
heating the liquid to a temperature greater than the melting temperature of the low melting temperature alloy; and
cooling the template such that the low melting temperature alloy solidifies.

22. The method of claim 21, wherein the step of heating the liquid occurs after the first microcomponents have been received into the recessed binding sites.

23. The method of claim 21, wherein the distinct shapes of the microcomponents include one or more shapes from the group comprising circular, square, rectangular, triangular, and cruciform.

24. The method of claim 21, wherein the metal pad interconnects are formed on only one side of the first microcomponents.

25. The method of claim 21, further comprising the steps of:
fabricating a plurality of second microcomponents having a second shape and a metal pad interconnect;
fabricating the template to also include a plurality of recessed binding sites shaped to receive the second microcomponents, the binding sites being electrically connected with an interconnect network, and further comprising a low melting temperature alloy; and
placing the second microcomponents into the liquid such that at least some of the second microcomponents are received into at least some of the recessed binding sites such that the received second microcomponent metal pad interconnects engage the low melting temperature alloy.

26. The method of claim 21, wherein the template includes a substrate formed from one of polyester and polyethylene terephthalate, and an epoxy-based clear negative photoresist.

27. The method of claim 21, wherein the heated liquid is selected from the group ethylene glycol and glycerol.

28. The method of claim 27, wherein the ethylene liquid is heated to about 70° C.

29. The method of claim 21, further comprising the steps of cleaning the microcomponents with a short piranha etch and rinsing the microcomponents with de-ionized water prior to placing the microcomponents in the liquid.

30. The method of claim 21, further comprising the step of recirculating a portion of the first micro components.

31. The method of claim 21, further comprising the step of agitating the heated liquid.
